(19) United States
(12) Patent Application Publication
(10) Pub. No.: US 2026/0099636 A1
(43) Pub. Date: Apr. 9, 2026

(54) CUSTOMIZABLE NOTIFICATIONS IN EXTENSIBLE OBJECT MODELING

(71) Applicant: Honeywell International Inc., Charlotte, NC (US)

(72) Inventors: Veeranagegowda Shivalingappa, Hiriyuru (IN); R. Dhawan Kumar, Hyderabad (IN); Agniraj Chatterji, Kolkata (IN); Sumanth Pachipulusu Lingesh, Bengaluru (IN); Rajesh Kulandaivel Sankarapandian, Cumming, GA (US)

(21) Appl. No.: 18/907,827

(22) Filed: Oct. 7, 2024

(51) Int. Cl. G06F 30/12

(52) U.S. Cl. CPC G06F 30/12

(57) ABSTRACT

Devices, methods, and systems for customizable notifications in extensible object modeling are described herein. One method includes providing, by a computing device, an interface for customizing an object template in an object modeling platform, receiving, via a first portion of the interface, a request to provide a notification corresponding to an object instance created using the object template, receiving, via a second portion of the interface, an indication of a cause that is to trigger a providing of the notification, receiving, via a third portion of the interface, an indication of a manner in which the notification is to be provided, customizing, by the computing device, the object template to provide the notification according to the indicated cause and the indicated manner of the notification, and providing, by the computing device, the notification according to the indicated manner responsive to an occurrence of the indicated cause.

### TECHNICAL FIELD

The present disclosure relates generally to devices, methods, and systems for customizable notifications in extensible object modeling.

### BACKGROUND

A platform for extensible object modeling provides customers and integrators the ability to configure and manage master data and digital models for a system, such an HVAC system, a fire system, or a security system, for instance. Digital models can represent objects such as sites, spaces, and/or assets (e.g., equipment), for instance, of the system.

Template-driven modeling allows users to define different object templates that include their own sets of data. Generally, the data of a template is configurable and can include attributes, relationships, metrics, etc.

### BRIEF DESCRIPTION OF THE DRAWINGS

FIG. 1 illustrates a networked computing system environment for customizable notifications in extensible object modeling, in accordance with one or more embodiments.

FIG. 2 is a screenshot of an example interface including a plurality of object templates, in accordance with one or more embodiments.

FIG. 3 is a screenshot of an example interface including a plurality of object instances, in accordance with one or more embodiments.

FIG. 4A is a portion of a screenshot of an example interface for customizing an object template, in accordance with one or more embodiments.

FIG. 4B is another portion of the screenshot of the example interface illustrated in FIG. 4A.

FIG. 5 is a screenshot of an example interface for customizing an instance, in accordance with one or more embodiments.

FIG. 6 is a screenshot of an example interface for customizing notifications, in accordance with one or more embodiments.

FIG. 7 illustrates an example of a method for customizable notifications in extensible object modeling, in accordance with one or more embodiments.

FIG. 8 is an example of a computing device for customizable notifications in extensible object modeling, in accordance with one or more embodiments.

### DETAILED DESCRIPTION

Devices, methods, and systems for customizable notifications in extensible object modeling are described herein. One method includes providing, by a computing device, an interface for customizing an object template in an object modeling platform, receiving, via a first portion of the interface, a request to provide a notification corresponding to an object instance created using the object template, receiving, via a second portion of the interface, an indication of a cause that is to trigger a providing of the notification, receiving, via a third portion of the interface, an indication of a manner in which the notification is to be provided, customizing, by the computing device, the object template to provide the notification according to the indicated cause and the indicated manner of the notification, and providing, by the computing device, the notification according to the indicated manner responsive to an occurrence of the indicated cause.

As previously discussed, a platform for extensible object modeling provides customers and integrators the ability to configure and manage master data and digital models for a system, such as an HVAC system, a fire system, or a security system, for instance. Digital models can represent objects such as sites, spaces, and/or assets (e.g., equipment), for instance, of the system.

Template-driven modeling allows users to define different object templates that include their own sets of data. The set of data included in a template reflects the type of object it represents. The types of data relevant to a “boiler” template, for example, will differ from the types of data relevant to a “smoke detector” template. Generally, the data of a template is configurable and can include attributes, relationships, metrics, etc.

Using a template, specific instances (referred to herein as “object instances” or simply “instances”) can be created. A template corresponds to a type of object being modeled, and an instance corresponds to a specific object of that type. As an example, the instance “Boiler_1356a1,” representing a specific boiler at a specific location of a facility, can be created from the template “boiler.” Templates can be arranged in a hierarchical structure in that a given template may be a parent template and/or a child template. For example, an “asset” template may have child templates for “fan” and “pump,” the latter of which may have its own child templates for “centrifugal pump” and “piston pump.”

Extensibility is a feature that provides the capability to customize template data during runtime. Additionally, new custom templates can be created with different sets of data by extending existing templates. Because of their hierarchical nature, modifications made to a template can propagate down to the child templates and the individual instances below it.

The present disclosure improves template-driven object modeling platforms by adding to their extensibility the option to configure customizable notifications associated with objects of the template. Embodiments include an interface configured to allow the creation and modification of object notifications. The interface provides a plurality of configurable options that allow a user to customize the type, manner, timing, and other aspects of object notifications. As an example, a first portion of the interface can receive a request to provide a notification corresponding to an object instance created using the object template, a second portion of the interface can receive an indication of a cause that is to trigger a providing of the notification, and a third portion of the interface can receive an indication of a manner in which the notification is to be provided. The object template can be customized to provide the notification according to the indicated cause and the indicated manner of the notification, and the notification can be provided in the indicated manner responsive to an occurrence of the indicated cause. Notifications in accordance with embodiments of the present disclosure can improve operations by reminding users of recommended maintenance and/or license expirations, for example, but can be configured to be provided to fulfil any suitable purpose.

As described further herein, notifications can refer to alerts, reminders, or other notifications. In some embodiments, notifications are configured to be provided based on a rule. In some embodiments, for instance, a notification can be provided responsive to an occurrence of an event. In some embodiments, a notification can be provided responsive to a threshold being exceeded. For example, a user can elect to be provided with a notification when a time since a manufacturing date of a particular asset has exceeded a threshold. In some embodiments, notifications are configured to be provided based on a schedule. For example, a user can elect to be provided with a maintenance notification for a particular asset on a biannual schedule. Notifications can be configured to include recommendations associated with an object (e.g., “filter change recommended”).

The manner in which notifications are provided is configurable via the interface. For instance, the manner in which a notification is displayed, indicated audibly, or delivered is configurable via the interface. The cause(s) of a notification being provided is configurable via the interface. Whether, or how, a notification is dismissible by a user is configurable via the interface. Which user(s) are authorized to dismiss a notification is configurable via the interface.

In the following detailed description, reference is made to the accompanying drawings that form a part hereof. The drawings show by way of illustration how one or more embodiments of the disclosure may be practiced.

These embodiments are described in sufficient detail to enable those of ordinary skill in the art to practice one or more embodiments of this disclosure. It is to be understood that other embodiments may be utilized and that mechanical, electrical, and/or process changes may be made without departing from the scope of the present disclosure.

As will be appreciated, elements shown in the various embodiments herein can be added, exchanged, combined, and/or eliminated so as to provide a number of additional embodiments of the present disclosure. The proportion and the relative scale of the elements provided in the figures are intended to illustrate the embodiments of the present disclosure and should not be taken in a limiting sense.

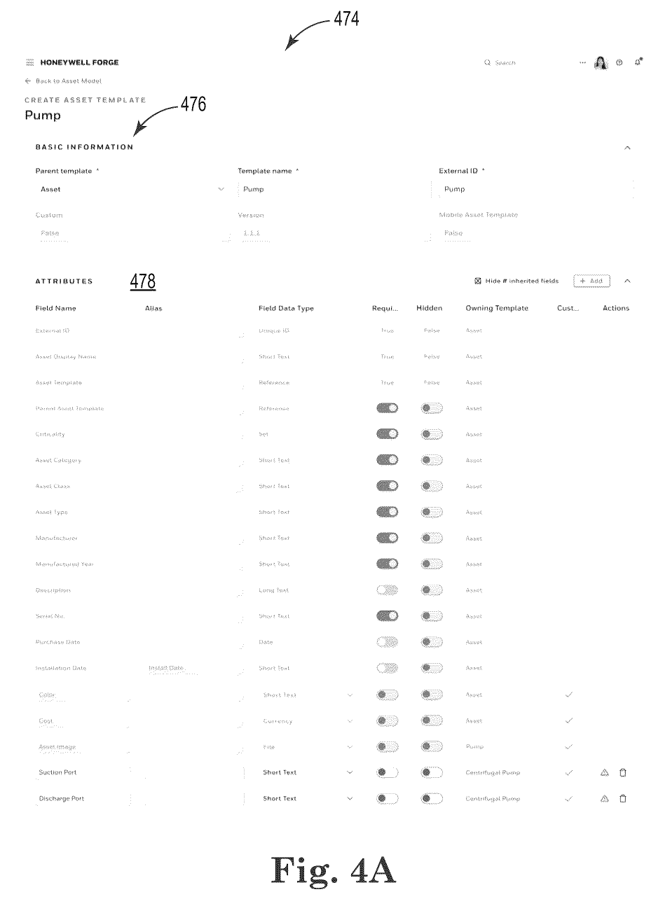

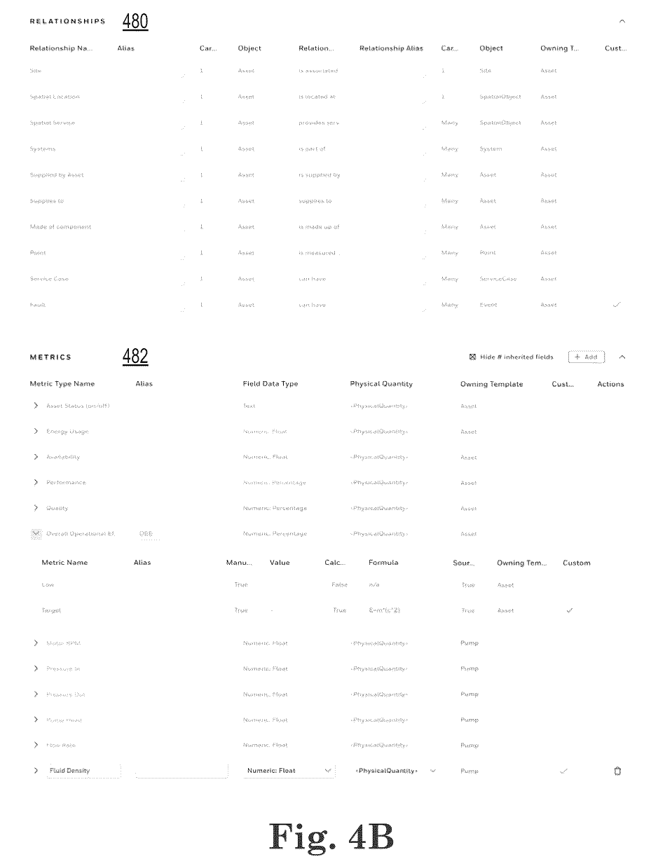

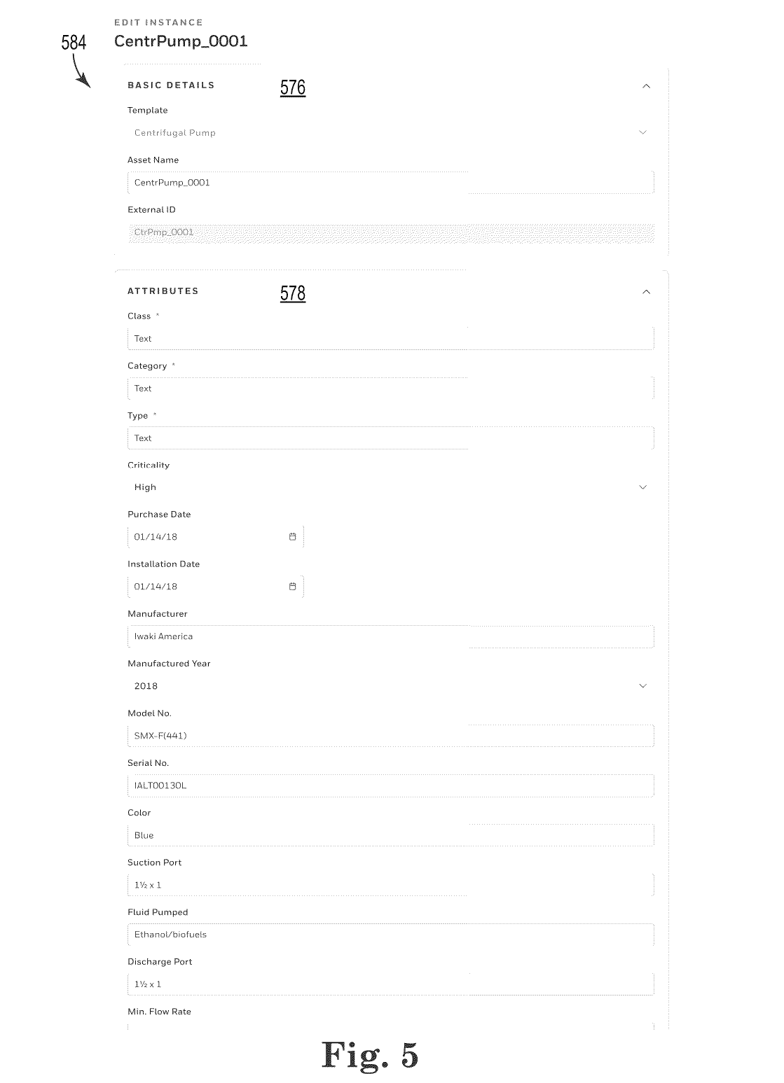

The figures herein follow a numbering convention in which the first digit or digits correspond to the drawing figure number and the remaining digits identify an element or component in the drawing. Similar elements or components between different figures may be identified by the use of similar digits. For example, 476 may reference element “76” in FIG. 4, and a similar element may be referenced as 576 in FIG. 5.

As used herein, “a”, “an”, or “a number of” something can refer to one or more such things, while “a plurality of” something can refer to more than one such things. For example, “a number of components” can refer to one or more components, while “a plurality of components” can refer to more than one component. Additionally, the designator “n”, as used herein, particularly with respect to reference numerals in the drawings, indicates that a number of the particular feature so designated can be included with a number of embodiments of the present disclosure.

An object modeling platform in accordance with the present disclosure is an extensible platform that is portable for deployment in any cloud or data center environment for providing an enterprise-wide, top to bottom view, displaying the status of processes, objects, people, and safety. The object modeling platform may include a number of layers including, for example, an extensible object model (EOM) that includes one or more knowledge graphs. The EOM may be a collection of application programming interfaces (APIs) that enables a seeded semantic object model to be extended. The extensible object model further enables a customer's knowledge graph to be built subject to the constraints expressed in the customer's semantic object model. A knowledge graph describes real world entities and their interrelations, organized in a graph. A knowledge graph defines possible classes and relations of entities in a schema, and enables the interrelating of potentially arbitrary entities and (iv) covers various topical domains. Knowledge graphs may include large networks of entities, their semantic types, properties, and relationships between entities. The entities may be physical entities or non-physical entities, such as data.

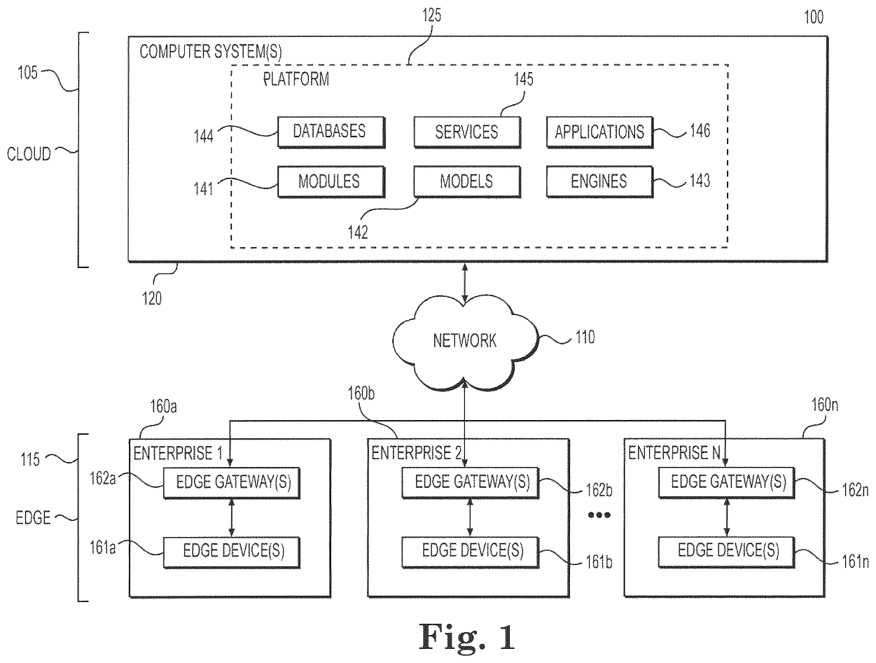

FIG. 1 illustrates a networked computing system environment 100 for customizable notifications in extensible object modeling, in accordance with one or more embodiments. As illustrated in FIG. 1, networked computing system environment 100 is organized into a plurality of layers including a cloud layer 105, a network layer 110, and an edge layer 115. As detailed further below, components of the edge 115 are in communication with components of the cloud 105 via network 110.

Network 110 may be any suitable network or combination of networks and may support any appropriate protocol suitable for communication of data to and from components of the cloud 105 and between various other components in the networked computing system environment 100 (e.g., components of the edge 115). Network 110 may include a public network (e.g., the Internet), a private network (e.g., a network within an organization), or a combination of public and/or private networks. Network 110 may be configured to provide communication between various components depicted in FIG. 1. Network 110 may comprise one or more networks that connect devices and/or components in the network layout to allow communication between the devices and/or components. For example, the network 110 may be implemented as the Internet, a wireless network, a wired network (e.g., Ethernet), a local area network (LAN), a Wide Area Network (WANs), Bluetooth, Near Field Communication (NFC), or any other type of network that provides communications between one or more components of the network layout. In some embodiments, network 110 may be implemented using cellular networks, satellite, licensed radio, or a combination of cellular, satellite, licensed radio, and/or unlicensed radio networks.

Components of the cloud 105 include one or more computer systems 120 that form an object modeling platform 125. Computer systems 120 may include any type or quantity of one or more processors and one or more data storage devices comprising memory for storing and executing applications or software modules of networked computing system environment 100. In one embodiment, the processors and data storage devices are embodied in server-class hardware, such as enterprise-level servers. For example, the processors and data storage devices may comprise any type or combination of application servers, communication servers, web servers, super-computing servers, database servers, file servers, mail servers, proxy servers, and/virtual servers. Further, the one or more processors are configured to access the memory and execute processor-readable instructions, which when executed by the processors configures the processors to perform a plurality of functions of the networked computing system environment 100.

Computer systems 120 further include one or more software components of the object modeling platform 125. For example, the software components of computer systems 120 may include one or more software modules to communicate with user devices and/or other computing devices through network 110. For example, the software components may include one or more modules 141, models 142, engines 143, databases 144, services 145, and/or applications 146, which may be stored in/by the computer systems 120 (e.g., stored on the memory). The one or more processors may be configured to utilize the one or more modules 141, models 142, engines 143, databases 144, services 145, and/or applications 146 when performing various methods described in this disclosure.

Accordingly, computer systems 120 may execute a cloud computing platform (e.g., object modeling platform 125) with scalable resources for computation and/or data storage, and may run one or more applications on the cloud computing platform to perform various computer-implemented methods described in this disclosure. In some embodiments, some of the modules 141, models 142, engines 143, databases 144, services 145, and/or applications 146 may be combined to form fewer modules, models, engines, databases, services, and/or applications. In some embodiments, some of the modules 141, models 142, engines 143, databases 144, services 145, and/or applications 146 may be separated into separate, more numerous modules, models, engines, databases, services, and/or applications. In some embodiments, some of the modules 141, models 142, engines 143, databases 144, services 145, and/or applications 146 may be removed while others may be added.

The computer systems 120 are configured to receive data from other components (e.g., components of the edge 115) of networked computing system environment 100 via network 110. Computer systems 120 are further configured to utilize the received data to produce a result. Information indicating the result may be transmitted to users via user computing devices over network 110. In some embodiments, the computer systems 120 may be referred to as a server system that provides one or more services including providing the information indicating the received data and/or the result(s) to the users. Computer systems 120 are part of an entity, which may include any type of company, organization, or institution that implements one or more services. In some examples, the entity may be a platform provider.

Components of the edge 115 include one or more enterprises 160a-160n each including one or more edge devices 161a-161n and one or more edge gateways 162a-162n. For example, a first enterprise 160a includes first edge devices 161a and first edge gateways 162a, a second enterprise 160b includes second edge devices 161b and second edge gateways 162b, and an nth enterprise 160n includes nth edge devices 161n and nth edge gateways 162n. As used herein, enterprises 160a-160n may represent any type of entity, facility, vehicle, etc. such as, for example, companies, divisions, buildings, manufacturing plants, warehouses, real estate facilities, laboratories, aircraft, spacecraft, automobiles, ships, boats, military vehicles, oil and gas facilities, or any other type of entity, facility, and/or vehicle that includes any number of local devices.

The objects (e.g., edge devices) 161a-161n may represent any of a variety of different types of devices that may be found within the enterprises 160a-160n. Objects 161a-161n are any type of device configured to access network 110, or be accessed by other devices through network 110, such as via an edge gateway 162a-162n. Objects 161a-161n may be IoT devices in some instances, which may therefore include any type of network-connected (e.g., Internet-connected) device. The objects 161a-161n may be sites, spaces, and/or assets. Assets can include, for example, sensors, actuators, processors, computers, valves, pumps, fans, ducts, vehicle components, cameras, displays, doors, windows, security components, HVAC components, factory equipment, and/or any other devices that may be connected to the network 110 for collecting, sending, and/or receiving information. Each object 161a-161n can include, or otherwise be in communication with, one or more controllers for selectively controlling a respective object 161a-161n and/or for sending/receiving information between the objects 161a-161n and the cloud 105 via network 110.

The edge gateways 162a-162n include devices for facilitating communication between the objects 161a-161n and the cloud 105 via network 110. For example, the edge gateways 162a-162n include one or more communication interfaces for communicating with the objects 161a-161n and for communicating with the cloud 105 via network 110. The communication interfaces of the edge gateways 162a-162n may include one or more cellular radios, Bluetooth, WiFi, near-field communication radios, Ethernet, or other appropriate communication devices for transmitting and receiving information. Multiple communication interfaces may be included in each gateway 162a-162n for providing multiple forms of communication between the objects 161a-161n, the gateways 162a-162n, and the cloud 105 via network 110. For example, communication may be achieved with the objects 161a-161n and/or the network 110 through wireless communication (e.g., WiFi, radio communication, etc.) and/or a wired data connection (e.g., a universal serial bus, an onboard diagnostic system, etc.) or other communication modes, such as a local area network (LAN), wide area network (WAN) such as the Internet, a telecommunications network, a data network, or any other type of network.

The edge gateways 162a-162n may also include a processor and memory for storing and executing program instructions to facilitate data processing. For example, the edge gateways 162a-162n can be configured to receive data from the objects 161a-161n and process the data prior to sending the data to the cloud 105. Accordingly, the edge gateways 162a-162n may include one or more software modules or components for providing data processing services and/or other services or methods of the present disclosure. In some cases, any of objects 161a-n and edge gateways 162a-n may have their functionality combined, omitted, or separated into any combination of devices. In other words, an object and its gateway need not necessarily be discrete devices.

The object modeling platform 125 of the present disclosure is a platform for enterprise performance management that uses real-time accurate models and visual analytics to deliver intelligent actionable recommendations for sustained peak performance of the enterprise 160a-160n. The object modeling platform 125 is an extensible platform that is portable for deployment in any cloud or data center environment for providing an enterprise-wide, top to bottom view, displaying the status of processes, nodes, people, and safety.

As used herein, “extensible” refers to the ability to extend a data model to include new properties/columns/fields, new classes/tables, and new relations. Thus, the object modeling platform 125 is extensible with regards to objects 161a-161n and the applications 146 that handle those objects 161a-161n. For example, when new objects 161a-161n are added to an enterprise 160a-160n system, the new objects 161a-161n will automatically appear in the object modeling platform 125 so that the corresponding applications 146 can understand and use the data from the new objects 161a-161n.

In some cases, templates are used to facilitate configuration of instances of objects 161a-161n in the model using common structures. A template defines the typical properties for the objects 161a-161n of a given enterprise 160a-160n for a certain type of object. For example, a template of a pump includes modeling the pump having inlet and outlet pressures, speed, flow, etc. The templates may also include hierarchical or derived types of objects 161a-161n to accommodate variations of a base type of object 161a-161n. For example, a reciprocating pump, a centrifugal pump, and a piston pump would each be a specialization of a base pump type and would each include additional properties in the template. As an additional example, an axial fan would be a specialization of a base fan type and would include additional properties of the template. Instances of the objects 161a-161n in the model are configured to match the actual, physical objects of the enterprise 160a-160n using the templates to define expected attributes of the object 161a-161n. Each attribute is configured either as a static value (e.g., capacity is 1000 BPH) or with a reference to a time series tag that provides the value.

In some embodiments, models and templates can be used to define calculations and analytics, and to define how the calculations and analytics relate to the objects 161a-161n. For example, a pump template can define pump efficiency calculations such that every time a pump is configured, the standard efficiency calculation is automatically executed for the pump. The calculation model defines the various types of calculations, the type of engine that should run the calculations, the input and output parameters, the preprocessing requirement and prerequisites, the schedule, etc. The actual calculation or analytic logic may be defined in the template or it may be referenced. Thus, the calculation model can be used to describe and control the execution of a variety of different process models. Calculation templates can be linked with the node templates such that when an instance is created, any associated calculation instances are also created with their input and output parameters linked to the appropriate attributes of the object.

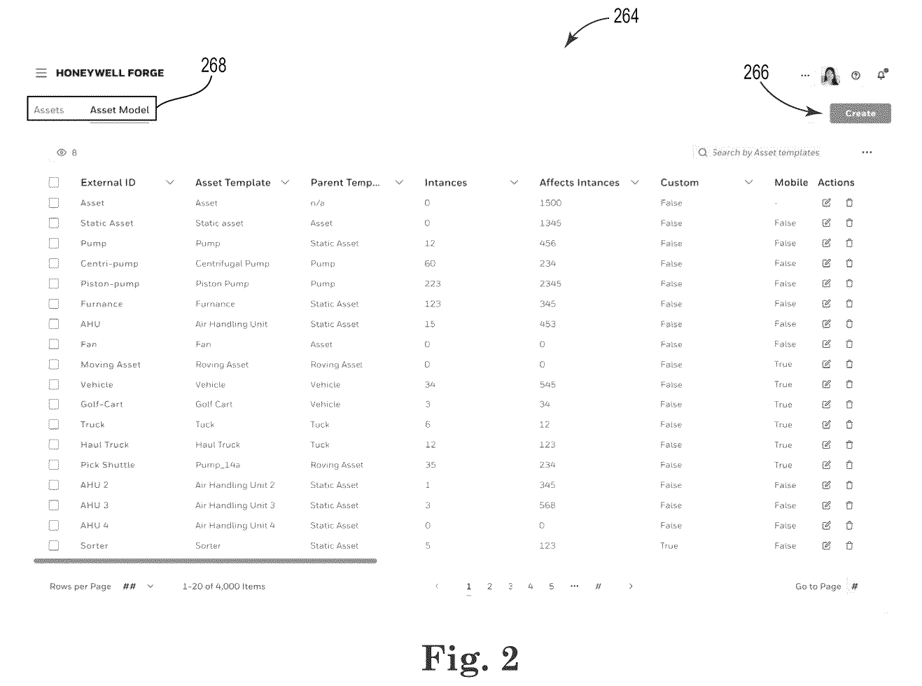

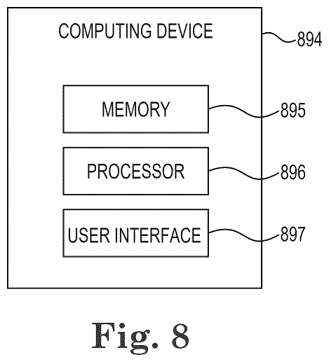

FIG. 2 is a screenshot of an example interface 264 including a plurality of object templates in accordance with one or more embodiments. FIG. 2 is a screenshot of an example interface 264 including a plurality of object templates in accordance with one or more embodiments. Interface 264 can be provided (e.g., displayed) as a user interface of a computing device, such as, for instance, user interface 897 of computing device 894 further described in connection with FIG. 8.

As illustrated in FIG. 2, the interface 264 includes a list of object types under the heading “External ID.” It is noted that in the example illustrated in FIG. 2 and elsewhere herein, the specific example of “asset” may be used rather than the broader term “object.” It is to be understood that such usage is not to be taken in a limiting sense; as previously discussed, objects in accordance with the present disclosure include assets, sites and spaces. The names of the templates that correspond to the objects include, for example, “pump,” “centrifugal pump,” piston pump,” “furnace,” “truck,” “static asset,” etc. Additional information corresponding to the templates can be listed in columns, as illustrated in FIG. 2, for instance. This information can include the type of each template, the parent template of each template, the quantity of instances of each template, the quantity of instances affected by each template, and whether each template is a custom template, among other information.

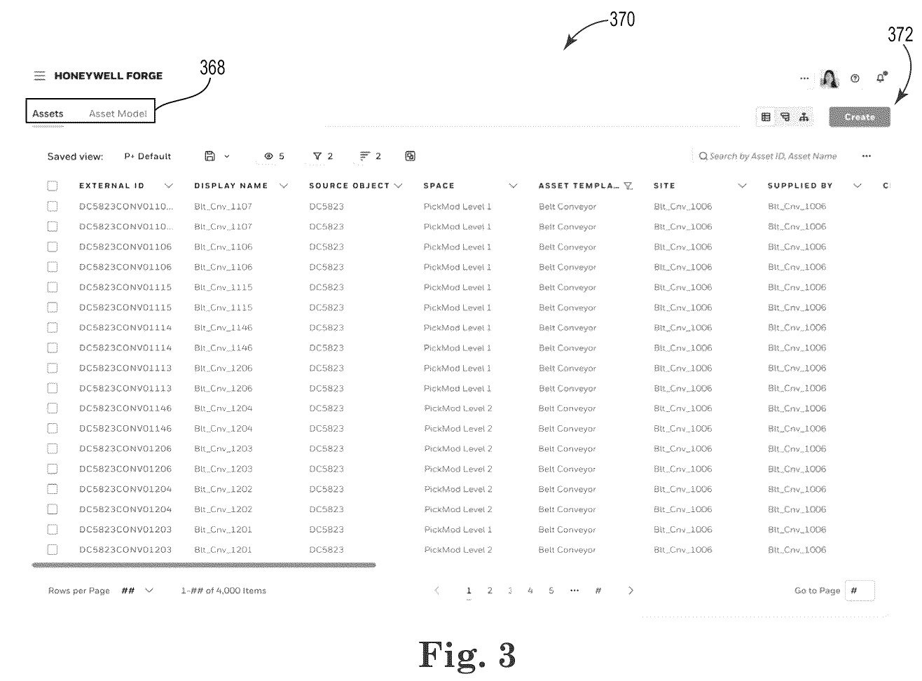

In some embodiments, selection of a template from the list illustrated in interface 264 causes the display of detailed information associated with the selected template. In some embodiments, selection of a template from the list illustrated in interface 264 allows the modification of the selected template. Selection of a display element (“create” button 266) can allow the creation of a new template using a different interface, described below in connection with FIG. 4. Selection of a toggling display element 268 can toggle the display to a plurality of object instances, which is described below in connection with FIG. 3.

FIG. 3 is a screenshot of an example interface including a plurality of object instances in accordance with one or more embodiments. Interface 370 can be provided (e.g., displayed) sn a user interface of a computing device, such as, for instance, user interface 897 of computing device 894 further described in connection with FIG. 8.

As illustrated in FIG. 3, the interface 370 includes a list of instance names under the heading “External ID.” The names of the instances include, for example, “DC5823CONVO1106,” “DC5823CONVO1115,” etc. Additional information corresponding to the instances can be listed in columns in interface 370, as illustrated in FIG. 3, for instance. This information can include the display name of each instance, the name of the object that each instance represents (e.g., “SOURCE OBJECT”), the space in which each source object is located, the template used to create each instance, the site in which each source object is located, and the name(s) of object(s) that supply each object.

In some embodiments, selection of an instance from the list illustrated in interface 370 causes the display of detailed information associated with the selected instance. In some embodiments, selection of an instance from the list illustrated in interface 370 allows the modification of the selected instance. Selection of a display element (“create” button 372) can allow the creation of a new instance using a different interface, described below in connection with FIG. 5. Selection of the toggling display element 368 can toggle the display to the plurality of object instances, described above in connection with FIG. 2.

FIG. 4A is a portion of a screenshot of an example interface for customizing an object template, in accordance with one or more embodiments. FIG. 4B is another portion of the screenshot of the example interface illustrated in FIG. 4A. FIGS. 4A and 4B are cumulatively referred to herein as “FIG. 4.”

FIG. 4 is a screenshot of an example interface 474 for customizing an object template in accordance with one or more embodiments. Interface 474 can be provided (e.g., displayed) as a user interface of a computing device, such as, for instance, user interface 897 of computing device 894 further described in connection with FIG. 8.

Creating an object template can include utilizing the interface 474 to specify the particular attributes, relationships, and metrics that will be available to be populated with specific instance information when the template is later used to create an instance (described below in connection with FIG. 5). Accordingly, as illustrated in FIG. 4, the interface 474 can include a plurality of portions: a basic information portion 476, an attributes portion 478, a relationships portion 480, and a metrics portion 482, though embodiments herein are not limited to these example portions. It is noted that the term “portion,” as referred to herein, is a unit of an interface (e.g., a display). In some embodiments, a portion refers to a subset of an interface, such as a window, for instance. In some embodiments, a portion refers to a display element (e.g., a button) of an interface. In some embodiments, a portion refers to a page that constitutes an entirety of a display.

The basic information portion 476 can include the parent template of the template being created, the name of the template being created, the External ID of the template being created, an indication of whether the template being created is a custom template, a version of the template being created, etc.

The attributes portion 478 can include attributes of the template being created. The attributes portion 478 can allow the customization of which attributes (e.g., attributes of objects represented by instances created using the template) are to be included in the template. Attributes may include, for example, display name, category, class, type, manufacturer, manufactured year, description, serial number, purchase date, installation date, etc. As the template being created in the example illustrated in FIG. 4 is a “pump” template, the attributes portion 478 is shown as including a “suction port” field and a “discharge port” field. It is to be understood that these specific fields may be present in a pump template and absent in a golf cart template, for instance.

The relationships portion 480 can include relationship information corresponding to the template being created. The relationships portion 480 can allow the customization of what relationship information (e.g., relationship information corresponding to objects represented by instances created using the template) is to be included in the template.

Relationship information may include, for example, site, spatial location, spatial service, etc.

The metrics portion 482 can include metrics of the template being created. The metrics portion 482 can allow the customization of which metrics (e.g., metrics corresponding to objects represented by instances created using the template) are to be included in the template. Metrics may include, for example, status, energy usage, availability, performance, motor revolutions per minute (RPM), pressure in, pressure out, flow rate, etc.

A user can indicate the basic details, attributes, relationships, and metrics to be included in a template via the basic details portion 476, the attributes portion 478, the relationships portion 480, and the metrics portion 482, respectively, of the interface 474. As such, a user can customize a variety of aspects of templates using the interface portions described in connection with FIG. 4.

FIG. 5 is a screenshot of an example interface 584 for customizing an instance in accordance with one or more embodiments. Interface 584 can be provided (e.g., displayed) as a user interface of a computing device, such as, for instance, user interface 897 of computing device 894 further described in connection with FIG. 8.

The example illustrated in FIG. 5 depicts an instance being created from the template previously described in connection with FIG. 4. For example, the instance “CentrPump_001,” having been created using the template previously created using the interface 474 (previously described in connection with FIG. 4) can be customized using the interface 584. Accordingly, the basic details portion 576, the attributes portion 578, and the metrics portion (not shown in FIG. 5) include the basic details, the attributes, and the metrics that were previously customized using the interface 474. In some embodiments, the values of the various basic details, attributes, and/or metrics are user-entered. In some embodiments, the values the values of the various basic details, attributes, and/or metrics are received from a device. For example, the values can be received via an optical scan of a bar code associated with the object or from a computing device. In some embodiments, the values of the various basic details, attributes, and/or metrics are received from the object itself or from a sensing device associated with the object (e.g., in real time).

Embodiments herein enhance the customization of templates by providing the ability to create and modify notifications corresponding to object instances created using object templates. In some embodiments, the interface 474, previously described in connection with FIG. 4, can include a portion configured to receive a request to provide a notification regarding the object. In some embodiments, such a portion may be entitled “NOTIFICATIONS” and may be displayed in a manner analogous to the basic details portion 476, the attributes portion 478, the relationships portion 480, and the metrics portion 482. In some embodiments, a portion of the interface dedicated to notifications may be presented separately (e.g., responsive to the selection of a display element in the interface 474).

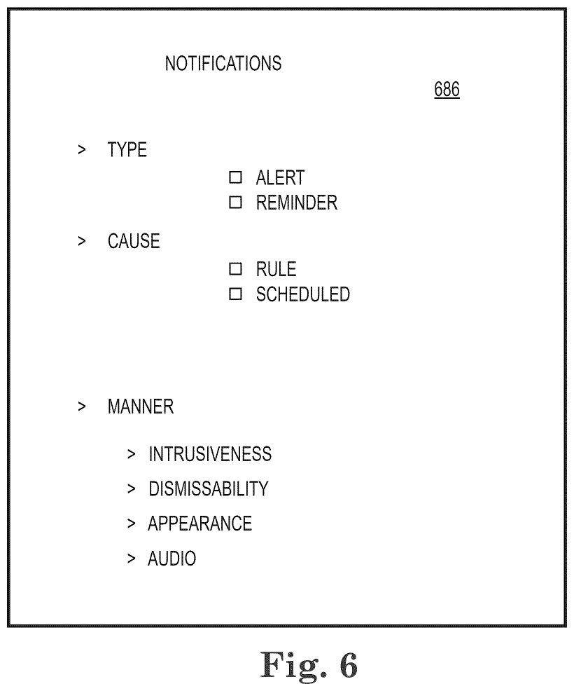

FIG. 6 is a screenshot of an example interface 686 for customizing notifications in accordance with one or more embodiments. Interface 686 can be provided (e.g., displayed) as a user interface of a computing device, such as, for instance, user interface 897 of computing device 894 further described in connection with FIG. 8.

The example illustrated in FIG. 6 depicts notifications being customized within the template previously described in connection with FIG. 4. As illustrated in FIG. 6, notifications can be customized by type, cause, and/or manner. In some embodiments, alert is a selectable option. In some embodiments, reminder is a selectable option. In practice, when creating an instance from a template, the selection of alert or reminder can cause the automatic population various other fields below. For example, a selection of “alert” can cause an increase of the intrusiveness and a decrease in the dismissibility (discussed further below) of notifications relative to a selection of “reminder.”

In some embodiments, the cause triggering notifications is a rule-based cause. That is, notifications can be configured to be provided based on a rule. Rule-based causes include the fulfilment of conditions, events, and/or thresholds, for instance.

A notification can be provided responsive to an occurrence of a condition and/or an event. For example, a notification reminding a user to inspect a pump can be provided responsive to the occurrence of an overflow. A notification can be provided responsive to a threshold being exceeded. For example, a user can elect to be provided with a notification to replace an equipment item or renew a license when a time since a manufacturing date of the item has exceeded a threshold. Accordingly, in some embodiments, the interface 686 can include a field configured to associate a metric of an object (e.g., motor RPM) represented by the object instance with a threshold (e.g., 200 RPM).

In some embodiments, the cause triggering notifications is a scheduled cause. That is, notifications can be configured to be provided based on a schedule. Such notifications can be one-time notifications (e.g., a notification provided six months in the future) or recurring notifications that recurs according to a pre-determined schedule (e.g., a notification provided every six months).

The manner in which notifications are provided is configurable via the interface 686. Manner, as described herein, refers to a notification's appearance, behavior, and/or method of communication. For instance, the manner in which a notification is displayed, indicated audibly, or delivered is configurable via the interface 686. The preference of a display style associated with the notification is configurable, including, for instance, the size, font, images, graphics, animations, etc. of a notification.

In some embodiments, the degree to which a notification is intrusive on an interface is configurable. For example, a notification associated with a warranty expiration may be configured to be less intrusive than a different notification associated with a license replacement. The former may be configured to be provided in small text on a peripheral portion of a display, whereas the latter may be configured to be provided in large text on a central portion of the display, for instance.

Whether, or how, a notification is susceptible of being dismissed by a user is configurable via the interface 686. For instance, whether, or how, a notification can be “snoozed” by a user is configurable via the interface 686. Which user(s) are authorized to dismiss and/or snooze a notification is configurable via the interface 686.

Notifications can be configured to include audio. The volume, duration, type, and other aspects of notification audio can be configured via the interface 686. Notifications can be configured to include information. The information can be descriptive of the object to which the notification corresponds, but embodiments are not so limited. In some embodiments, for instance, notifications can be configured to include recommendations associated with an object (e.g., “filter change recommended”).

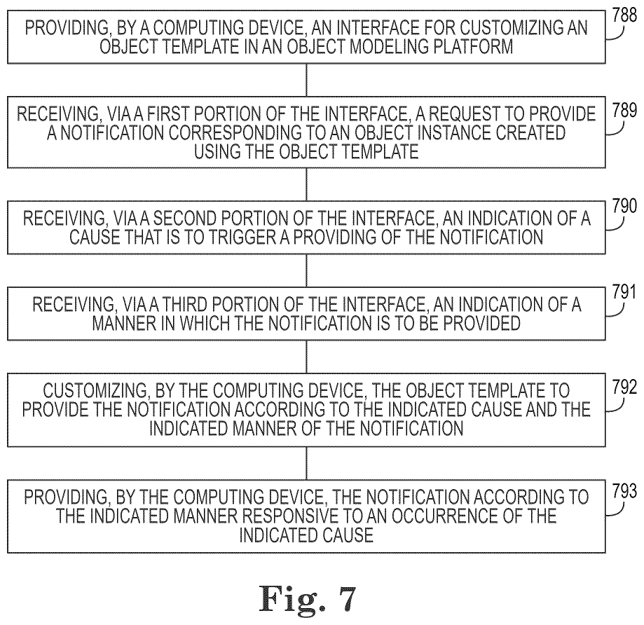

FIG. 7 illustrates an example of a method for customizable notifications in extensible object modeling in accordance with one or more embodiments. The method can be performed by, for example, a computing device such as that described below connection with FIG. 8, for instance.

At 788, the method includes providing, by the computing device, an interface (e.g., interfaces 474 and/or 686 previously described in connection with FIGS. 4 and 6, respectively) for customizing an object template in an object modeling platform. At 789, the method includes receiving, via a first portion of the interface, a request to provide a notification corresponding to an object instance created using the object template. Such a portion may be entitled “type” and may be displayed in a manner analogous to that previously described in connection with FIG. 6. For instance, the first portion may include a plurality of selectable types of notifications (e.g., alert and reminder), and a selection of one of the types can be received, as previously described in connection with FIG. 6. In some embodiments, a portion of the interface dedicated to notifications may be presented separately (e.g., responsive to the selection of a display element in the interface 474, previously described in connection with FIG. 4).

At 790, the method includes receiving, via a second portion of the interface, an indication of a cause that is to trigger a providing of the notification. Such a portion may be entitled “cause” and may be displayed in a manner analogous to that previously described in connection with FIG. 6. As previously discussed, causes can be selectable via the interface and can include rule-based causes and/or scheduled causes, for example. For instance, the second portion may include a plurality of selectable causes (e.g., rule-based and scheduled), and a selection of the indicated cause from the plurality of selectable causes can be received, as previously described in connection with FIG. 6. The indicated cause can be, for instance, a recurring cause, an occurrence of an event, or a threshold associated with the object being exceeded, as previously described herein.

At 791, the method includes receiving, via a third portion of the interface, an indication of a manner in which the notification is to be provided. In some embodiments, the manner is selectable via the interface and includes configurable options corresponding to appearance of the notification, information regarding the objection instance included in the notification, sound(s) associated with the notification, the level of intrusiveness of the notification, and/or whether the notification is dismissible by a user, among others. For instance, the portion may include a plurality of selectable manners (e.g., intrusiveness, dismissibility, appearance, and audio), and a selection of the indicated manner from the plurality of selectable manners can be received, as previously described in connection with FIG. 6.

At 792, the method includes customizing, by the computing device, the object template to provide the notification according to the indicated cause and the indicated manner of the notification. Once a user is finished customizing the template with the desired notification configurations, the template can be saved for later use in creating instances. For instance, the object instance can be created using the customized object template. Each individual instance can be further customized such that notifications can be unique to each instance. At 793, the method includes providing, by the computing device, the notification according to the indicated manner responsive to an occurrence of the indicated cause.

FIG. 8 is an example of a computing device 894 for customizable notifications in extensible object modeling, in accordance with one or more embodiments. As illustrated in FIG. 8, the computing device 894 can include a memory 895, a processor 896, and a user interface 897 for customizable notifications in extensible object modeling, in accordance with the present disclosure.

The memory 895 can be any type of storage medium that can be accessed by the processor 896 to perform various examples of the present disclosure. For example, the memory 895 can be a non-transitory computer readable medium having computer readable instructions (e.g., executable instructions/computer program instructions) stored thereon that are executable by the processor 896 for customizable notifications in extensible object modeling in accordance with the present disclosure.

The memory 895 can be volatile or nonvolatile memory. The memory 895 can also be removable (e.g., portable) memory, or non-removable (e.g., internal) memory. For example, the memory 895 can be random access memory (RAM) (e.g., dynamic random access memory (DRAM) and/or phase change random access memory (PCRAM)), read-only memory (ROM) (e.g., electrically erasable programmable read-only memory (EEPROM) and/or compact-disc read-only memory (CD-ROM)), flash memory, a laser disc, a digital versatile disc (DVD) or other optical storage, and/or a magnetic medium such as magnetic cassettes, tapes, or disks, among other types of memory.

Further, although memory 895 is illustrated as being located within computing device 894, embodiments of the present disclosure are not so limited. For example, memory 895 can also be located internal to another computing resource (e.g., enabling computer readable instructions to be downloaded over the Internet or another wired or wireless connection).

The processor 896 may be a central processing unit (CPU), a semiconductor-based microprocessor, and/or other hardware devices suitable for retrieval and execution of machine-readable instructions stored in the memory 895.

In some embodiments, the instructions include instructions to provide, in user interface 897, an interface for customizing an object template in an object modeling platform. The interface can include a first portion configured to receive a request to provide a notification corresponding to an object instance created using the object template.

The interface can include a second portion configured to receive an indication of a cause that is to trigger a providing of the notification. In some embodiments, the instructions include instructions to include, in the second portion, a plurality of selectable schedule options for providing the notification. In some embodiments, the instructions include instructions to include, in the second portion, a field configured to receive an indication of an amount of time following a date particular to the object instance for providing the notification. The date can be, for instance, the manufacturing date, the purchase date, or the installation date of the object represented by the object instance. In some embodiments, the instructions include instructions to include, in the second portion, a field configured to associate a metric of an object represented by the object instance with a threshold for providing the notification.

The interface can include a third portion configured to receive an indication of a manner in which the notification is to be provided. In some embodiments, the third portion includes a field configured to receive a preference of a display style in which the notification is to be provided. In some embodiments, the third portion includes a field configured to receive a preference of a sound to be included in the notification. In some embodiments, the third portion includes a field configured to receive a preference associated with snoozing the notification.

In some embodiments, the instructions include instructions to display the first portion, the second portion, and the third portion in separate windows in the interface. In some embodiments, the instructions include instructions to display the first portion, the second portion, and the third portion in a single window in the interface. In some embodiments, the instructions include instructions to customize the object template to provide the notification according to the indicated cause and the indicated manner of the notification and provide the notification according to the indicated manner responsive to an occurrence of the indicated cause.

As shown in FIG. 8, computing device 894 can include a user interface 897. A user of computing device 894 can interact with computing device 894 via user interface 897. For example, the user interface 897 can provide (e.g., display and/or present) information to the user of computing device 894, and/or receive information from (e.g., input by) the user of computing device 894. For instance, in some embodiments, user interface 897 can include a graphical user interface (GUI) that can provide and/or receive information to and/or from the user of computing device 894. The GUI can be, for instance, a touch-screen (e.g., the GUI can include touch-screen capabilities). As an additional example, user interface 897 (e.g., the GUI) can include a keyboard and/or mouse. However, embodiments of the present disclosure are not limited to a particular type of user interface.

As an example, user interface 897 can provide (e.g., display) the screenshots previously described in connection with FIGS. 2, 3, 4, 5, and 6 to a user of computing device 894. For instance, user interface 897 can provide (e.g., display) an interface for customizing an object template in an object modeling platform, as previously described herein. Further, user interface 897 can receive selections of causes, manners, etc., as previously described herein.

The user interface 897 can be localized to any language. For example, the user interface 897 can display information in any language, such as English, Spanish, German, French, Mandarin, Arabic, Japanese, Hindi, etc.

Although specific embodiments have been illustrated and described herein, those of ordinary skill in the art will appreciate that any arrangement calculated to achieve the same techniques can be substituted for the specific embodiments shown. This disclosure is intended to cover any and all adaptations or variations of various embodiments of the disclosure.

It is to be understood that the above description has been made in an illustrative fashion, and not a restrictive one. Combination of the above embodiments, and other embodiments not specifically described herein will be apparent to those of skill in the art upon reviewing the above description.

The scope of the various embodiments of the disclosure includes any other applications in which the above structures and methods are used. Therefore, the scope of various embodiments of the disclosure should be determined with reference to the appended claims, along with the full range of equivalents to which such claims are entitled.

In the foregoing Detailed Description, various features are grouped together in example embodiments illustrated in the figures for the purpose of streamlining the disclosure. This method of disclosure is not to be interpreted as reflecting an intention that the embodiments of the disclosure require more features than are expressly recited in each claim.

Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
providing, by a computing device, an interface for customizing an object template in an object modeling platform;
receiving, via a first portion of the interface, a request to provide a notification corresponding to an object instance created using the object template;
receiving, via a second portion of the interface, an indication of a cause that is to trigger a providing of the notification;
receiving, via a third portion of the interface, an indication of a manner in which the notification is to be provided;
customizing, by the computing device, the object template to provide the notification according to the indicated cause and the indicated manner of the notification; and
providing, by the computing device, the notification according to the indicated manner responsive to an occurrence of the indicated cause.

2. The method of claim 1, wherein the notification relates to maintenance of an object represented by the object instance.

3. The method of claim 1, wherein the method includes:
providing, via the second portion of the interface, a plurality of selectable causes to trigger a providing of the notification; and
receiving, via the second portion of the interface, a selection of the indicated cause from the plurality of selectable causes.

4. The method of claim 1, wherein the indicated cause is a recurring cause.

5. The method of claim 4, wherein the indicated cause recurs according to a pre-determined schedule.

6. The method of claim 1, wherein the indicated cause is an occurrence of an event.

7. The method of claim 1, wherein the indicated cause is a threshold associated with the object instance being exceeded.

8. The method of claim 1, wherein the method includes:
providing, via the third portion of the interface, a plurality of selectable manners in which the notification is to be provided; and
receiving, via the third portion of the interface, a selection of the indicated manner from the plurality of selectable manners.

9. The method of claim 1, wherein the method includes providing, via the third portion of the interface, a plurality of options corresponding to:
an appearance of the notification;
information regarding the object instance included in the notification;
a sound associated with the notification;
a level of intrusiveness of the notification; and
whether the notification is dismissible by a user.

10. A non-transitory machine-readable medium having instructions stored thereon which, when executed by a processor, cause the processor to:
provide an interface for customizing an object template in an object modeling platform, wherein the interface includes:
a first portion configured to receive a request to provide a notification corresponding to an object instance created using the object template;
a second portion configured to receive an indication of a cause that is to trigger a providing of the notification; and
a third portion configured to receive an indication of a manner in which the notification is to be provided;
customize the object template to provide the notification according to the indicated cause and the indicated manner of the notification; and
provide the notification according to the indicated manner responsive to an occurrence of the indicated cause.

11. The medium of claim 10, including instructions to display the first portion, the second portion, and the third portion in separate windows in the interface.

12. The medium of claim 10, including instructions to display the first portion, the second portion, and the third portion in a single window in the interface.

13. The medium of claim 10, including instructions to include, in the second portion, a plurality of selectable schedule options for providing the notification.

14. The medium of claim 10, including instructions to include, in the second portion, a field configured to receive an indication of an amount of time following a date particular to the object instance for providing the notification.

15. The medium of claim 14, wherein the date particular to the object instance is a manufacturing date, a purchase date, or an installation date of an object represented by the object instance.

16. The medium of claim 10, including instructions to include, in the second portion, a field configured to associate a metric of an object represented by the object instance with a threshold for providing the notification.

17. A computing device for customizing an object template in an object modeling platform, comprising:
a user interface;
a processing resource; and
a memory resource storing non-transitory machine-readable instructions to cause the processing resource to:
provide, in the interface, an interface for customizing an object template in an object modeling platform, wherein the interface includes:
a first portion configured to receive a request to provide a notification corresponding to an object instance created using the object template;
a second portion configured to receive an indication of a cause that is to trigger a providing of the notification; and
a third portion configured to receive an indication of a manner in which the notification is to be provided;
customize the object template to provide the notification according to the indicated cause and the indicated manner of the notification;
create the object instance using the customized object template; and
provide the notification according to the indicated manner responsive to an occurrence of the indicated cause.

18. The system of claim 17, wherein the third portion includes a field configured to receive a preference of a display style in which the notification is to be provided.

19. The system of claim 17, wherein the third portion includes a field configured to receive a preference of a sound to be included in the notification.

20. The system of claim 17, wherein the third portion includes a field configured to receive a preference associated with snoozing the notification.
